(19) United States
(12) Patent Application Publication
(10) Pub. No.: US 2025/0070049 A1
(43) Pub. Date: Feb. 27, 2025

(54) SEMICONDUCTOR RIGID CHIP-SCALE PACKAGE AND METHOD OF MAKING THE SAME

(71) Applicant: ALPHA AND OMEGA SEMICONDUCTOR INTERNATIONAL LP, TORONTO (CA)

(72) Inventors: Lin Lv, Shanghai (CN); Zhen Yang, Kunshan (CN); Shuhua Zhou, Shanghai (CN); Long-Ching Wang, Cupertino, CA (US)

(73) Assignee: ALPHA AND OMEGA SEMICONDUCTOR INTERNATIONAL LP, TORONTO (CA)

(21) Appl. No.: 18/882,783

(22) Filed: Sep. 12, 2024

Related U.S. Application Data
(63) Continuation-in-part of application No. 18/236,856, filed on Aug. 22, 2023.

(51) Int. Cl. H01L 23/00; H01L 21/3205; H01L 21/78

(52) U.S. Cl. CPC H01L 23/562; H01L 21/32051; H01L 21/78

(57) ABSTRACT

A semiconductor package comprises a semiconductor substrate, a plurality of contact pads, a seed layer, a first thick metal layer, a second thick metal layer, and a coating metal layer. Direct attachment of the first thick metal layer and the second thick metal layer comprises bonded metal atoms. The first thick metal layer and the second thick metal layer are bonded by an SAB process. A method comprises the steps of providing an upper device portion, providing a lower carrier portion, applying an SAB process, applying a de-bonding process, applying a tape, applying a singulation process, and removing the tape.

### FIELD OF THE INVENTION

This invention relates generally to a semiconductor rigid chip-scale package and a method of making a plurality of semiconductor packages. More particularly, the present invention relates to a semiconductor package made by the steps including a surface activated bonding (SAB) process.

### BACKGROUND OF THE INVENTION

Chip scaled package (CSP) dies are generally required to be connected to printed circuit boards (PCBs). To meet specific PCB requirement, for example, embedded PCB technology, overall thickness of a CSP die may be less than 100 microns. U.S. Pat. No. 10,991,660 and US Patent Application Publication No. 2019/0189569 to Wang et al. disclose a semiconductor package having a thickness of the semiconductor substrate equal to or less than 50 microns. A thickness of a semiconductor substrate of a semiconductor package of the present disclosure may be less than 35 microns so as being ultra-thin. In such ultra-thin substrate devices, stresses induced by the manufacturing process, especially in grinding and polishing process, or metal layer deposition process, can cause warpage or even cracking of the semiconductor substrate. It is because the thin substrates do not provide sufficient mechanical strength to sustain the stresses. Conventional solutions include addition of mechanical strengthen layers, such as metal layer or molding compound layer, at the back surface of the substrate to increase the mechanical strength of the devices. However, the addition of such mechanical strengthen layers not only increases the overall thickness of the devices, but also lead to long term reliability issues for mismatching thermal and mechanical properties of different materials. This present disclosure provides an improved solution by attaching two metal layers with opposite stress states to the substrate. An SAB process is applied to bond the two metal layers with opposite stress states to reduce the warpage of the semiconductor substrate.

The semiconductor package of present disclosure excludes a compound layer (for example, a compound layer 180 of FIG. 3 and paragraph of US Patent Application Publication No. 2023/0307325 to Lv et al.). The semiconductor package of present disclosure excludes a molding encapsulation (for example, a molding encapsulation 198 of FIG. 1 and paragraph [0013] of 2023/0420340). The semiconductor package of present disclosure excludes an adhesive layer between a first copper layer and a second copper layer.

### SUMMARY OF THE INVENTION

A semiconductor package comprises a semiconductor substrate, a plurality of contact pads, a seed layer, a first thick metal layer, a second thick metal layer, and a coating metal layer. Direct attachment of the first thick metal layer and the second thick metal layer comprises bonded metal atoms. The first thick metal layer and the second thick metal layer are bonded by an SAB process. In examples of the present disclosure, the first thick metal layer is a first copper layer. The second thick metal layer is a second copper layer. Direct attachment of the first copper layer and the second copper layer comprises bonded copper atoms. The first copper layer and the second copper layer are bonded by an SAB process.

A method for fabricating a plurality of semiconductor packages is disclosed. The method comprising the steps of providing an upper device portion, providing a lower carrier portion, applying an SAB process, applying a de-bonding process, applying a tape, applying a singulation process, and removing the tape.

### BRIEF DESCRIPTION OF THE DRAWINGS

FIG. 1 shows a cross-sectional view of a semiconductor package in examples of the present disclosure.

FIG. 2 is a flowchart of a process to develop a plurality of semiconductor packages in examples of the present disclosure.

FIG. 3 is a flowchart of a process to prepare an upper device portion in examples of the present disclosure.

FIG. 4 is a flowchart of a process to prepare a lower carrier portion in examples of the present disclosure.

FIGS. 5A, 5B, 5C, 5D, 5E, and 5F show the cross sections of the corresponding sub-steps of the process of FIG. 3 in examples of the present disclosure.

FIGS. 6A, 6B, 6C, and 6D show the cross sections of the corresponding sub-steps of the process of FIG. 4 in examples of the present disclosure.

FIGS. 7A, 7B, 7C, and 7D show the cross sections of the corresponding steps of the process of FIG. 2 in examples of the present disclosure.

### DETAILED DESCRIPTION OF THE INVENTION

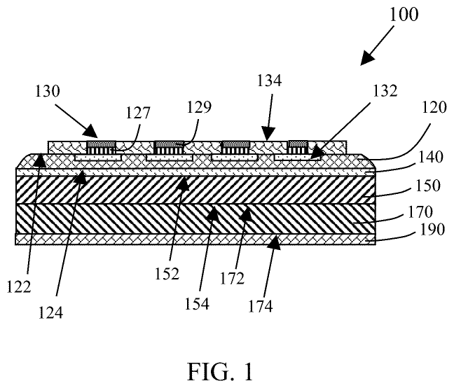

FIG. 1 shows a cross-sectional view of a semiconductor package 100 in examples of the present disclosure. The semiconductor package 100 comprises a semiconductor substrate 120, a plurality of contact pads 130, a seed layer 140, a first thick metal layer 150, and a second thick metal layer 170. Although other metal materials may be used, copper is preferred for the first thick metal layer 150 and the second thick metal layer 170 due to its excellent mechanical strength and electrical and thermal conductivities. In some examples of the present disclosure, the semiconductor package 100 may further comprise a coating metal layer 190 attached to the second thick metal layer 170.

The language “thick” of the first thick metal layer 150 and the second thick metal layer 170 is referred to as the following. In examples of the present disclosure, a thickness of the seed layer 140 is smaller than a thickness of the first thick metal layer 150. A thickness of the coating metal layer 190 is smaller than a thickness of the second thick metal layer 170. A thickness of the seed layer 140 is in a range from 0.1 micron to 0.5 micron. A thickness of the first thick metal layer 150 is in a range from 10 to 40 microns. A thickness of the coating metal layer 190 is in a range from 0.1 micron to 0.5 micron. A thickness of the second thick metal layer 170 is in a range from 10 to 45 microns.

In examples of the present disclosure, the semiconductor package 100 is a common-drain metal-oxide-semiconductor field-effect transistor (MOSFET) chip scale package (CSP) for battery protection application. Two gates and a plurality of sources are on a front surface of the common-drain MOSFET CSP. A common-drain is on a back surface of the common-drain MOSFET CSP. In one example, a horizontal dimension of the semiconductor package 100 is 3.4 mm by 2.0 mm. In examples of the present disclosure, a total thickness variation (TTV) of the semiconductor package 100 is less than 3 microns.

The semiconductor substrate 120 has a front surface 122 and a back surface 124 opposite the front surface 122 of the semiconductor substrate 120. The plurality of contact pads 130 are attached to the front surface 122 of the semiconductor substrate 120. The seed layer 140 is directly attached to the back surface 124 of the semiconductor substrate 120. In one example, the seed layer 140 comprises Ti metal layer. In another example, the seed layer 140 comprise Ti and Cu.

The first thick metal layer 150 has a front surface 152 and a back surface 154 opposite the front surface 152 of the first thick metal layer 150. The front surface 152 of the first thick metal layer 150 is attached to the back surface 124 of the semiconductor substrate 120 through seed layer 140. The second thick metal layer 170 has a front surface 172 and a back surface 174 opposite the front surface 172 of the second thick metal layer 170. The front surface 172 of the second thick metal layer 170 is bonded to the back surface 154 of the first thick metal layer 150. The first thick metal layer 150 and the second thick metal layer 170 have opposite stress states. The first thick metal layer 150 applies a first stress onto the semiconductor substrate 120. The second thick metal layer 170 applies a second stress opposite the first stress onto the first copper layer and balances out at least a portion of the first stress to reduce the overall stress of the semiconductor substrate 120. Warpage of the semiconductor substrate due to stress is reduced. Furthermore, the first thick metal layer 150 and the second thick metal layer 170 have substantial identical thermal mechanical properties such that the device will maintain its physical shape without deformation when subject to thermal stress. The semiconductor package 100 may further comprise a coating metal layer 190. The coating metal layer 190 has a front surface 192 and a back surface 194 opposite the front surface 192 of the coating metal layer 190. The front surface 192 of the coating metal layer 190 is directly attached to the back surface 174 of the second thick metal layer 170. The back surface 194 of the coating metal layer 190 may form the exterior back surface of the semiconductor package 100. The coating metal layer 190 protects the second thick metal layer 170 thus preventing oxidation of the second thick metal layer 170. In one example, the coating metal layer 190 comprises titanium (Ti). In another example, the coating metal layer 190 comprises nickel (Ni).

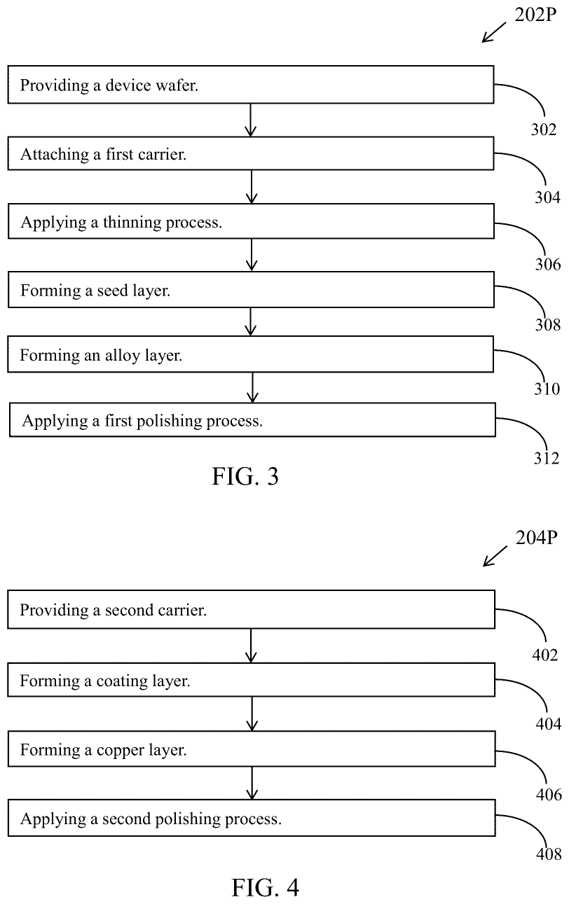

In examples of the present disclosure, the semiconductor package 100 excludes a compound layer (for example, a compound layer 180 of FIG. 3 and paragraph of US Patent Application Publication No. 2023/0307325 to Lv et al.). The semiconductor package 100 excludes a molding encapsulation (for example, a molding encapsulation 198 of FIG. 1 and paragraph [0013] of 2023/0420340).

In examples of the present disclosure, the bonding between the first thick metal layer 150 and the second thick metal layer 170 may be achieved by any known metal-metal bonding methods. In preferred examples, direct attachment of the first thick metal layer 150 and the second thick metal layer 170 is achieved by bonded metal atoms without intermedia adhesive layer. In one example, the first thick metal layer 150 and the second thick metal layer 170 are bonded by an SAB process.

In examples of the present disclosure, each of the plurality of contact pads 130 contains a gold layer 129 on top of a nickel layer 127 and a plurality of aluminum sections 132 at the bottom. Alternatively, copper layer may be deposited on top of the plurality of aluminum sections 132 to form the plurality of contact pads 130. The plurality of aluminum sections 132 are disposed at the front surface 122 of the semiconductor substrate 120. The plurality of passivation sections 134 extend above the plurality of aluminum sections 132. The plurality of passivation sections 134 contain polyimide. In examples of the present disclosure, a thickness of the plurality of passivation sections 134 is in a range from 5 microns to 7 microns. A thickness of the nickel layer 127 is in a range from 3 microns to 5 microns. A thickness of the gold layer 129 is in a range from 0.04 micron to 0.05 micron. A thickness of the plurality of aluminum sections 132 is in a range from 4 microns to 7 microns.

In examples of the present disclosure, a thickness of the semiconductor substrate 120 is less than 50 microns, preferable in a range from 15 microns to 35 microns. A sum of a thickness of the first thick metal layer 150 and a thickness of the second thick metal layer 170 is in a range from 25 microns to 80 microns. The lower limit 25 microns is to maintain the conductivity of the first thick metal layer 150 and the second thick metal layer 170 above a pre-determined conductivity value. The upper limit 80 microns is to maintain total thickness of the semiconductor package 100 below a pre-determined thickness value.

Bonded metal atoms attaching the second thick metal layer 170 to the first thick metal layer 150 facilitate the direct bonding between the second thick metal layer 170 and the first thick metal layer 150 thereby balancing the stress applied to the semiconductor substrate 120. Therefore, warpage of the semiconductor package 100 is reduced under thermal stress. In examples of the present disclosure, the first thick metal layer 150 is a first copper layer. The second thick metal layer 170 is a second copper layer. Bonded copper atoms attaching the second copper layer to the first copper layer facilitate the direct bonding between the two copper layers thereby balancing the stress applied to the semiconductor substrate 120. Therefore, warpage of the semiconductor package 100 is reduced even under thermal stress.

In examples of the present disclosure, the thickness of the second thick metal layer 170 is selected to cancel a warpage of the semiconductor substrate and the first thick metal layer when the semiconductor package 100 is subjected to thermal stress. In one example the first thick metal layer 150 and the second thick metal layer 170 are formed by plating with substantially identical condition. In another example, the first thick metal layer 150 is thinner than the second thick metal layer 170.

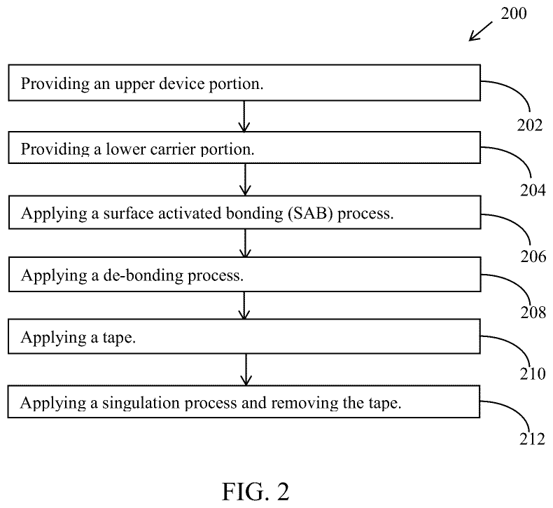

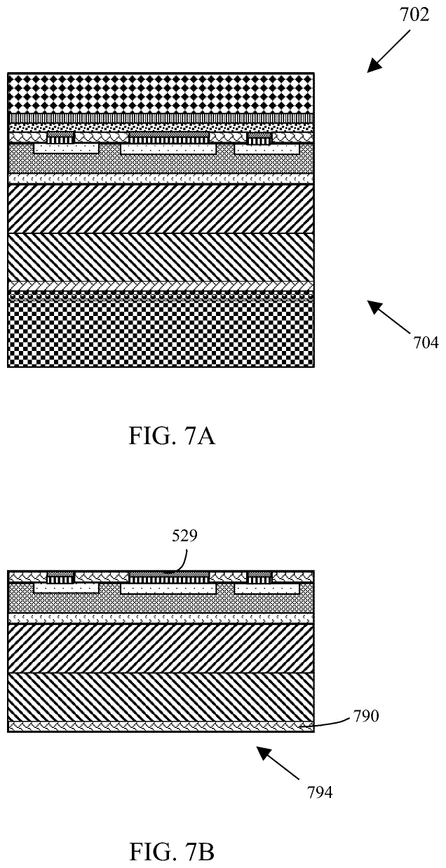

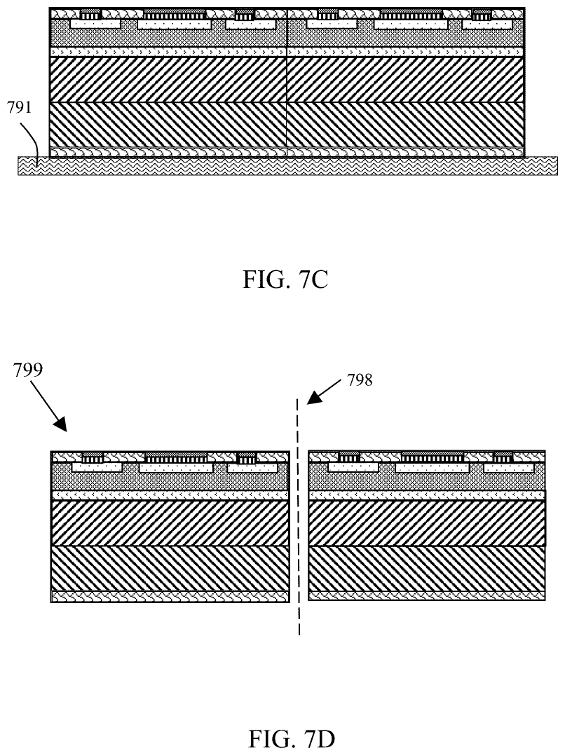

FIG. 2 is a flowchart of a process 200 to develop a plurality of semiconductor packages in examples of the present disclosure. FIGS. 7A, 7B, 7C, and 7D show the cross sections of the corresponding steps of the process 200 of FIG. 2 in examples of the present disclosure. Though copper is used for the first thick metal layer and the second thick metal layer in the process of making illustrated here, the same process flow is applicable to other metals, such as Al. For simplicity, the process to make a single semiconductor package is shown in FIGS. 7A and 7B and the process to make two semiconductor packages are shown in FIGS. 7C and 7D. The number of semiconductor packages fabricated by a single wafer may vary. The process 200 may start from block 202.

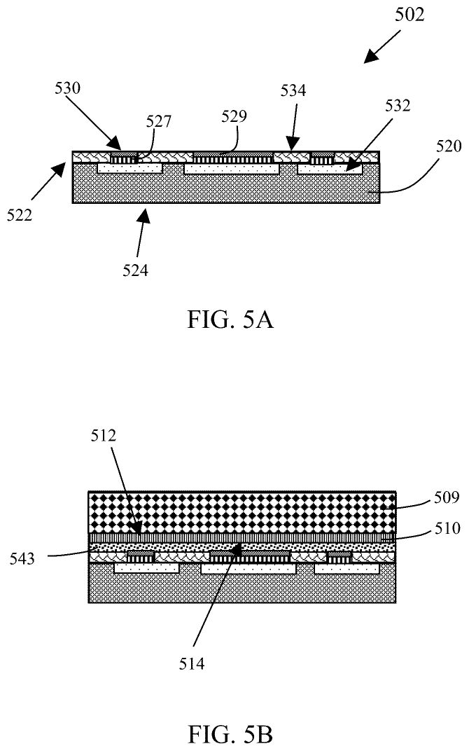

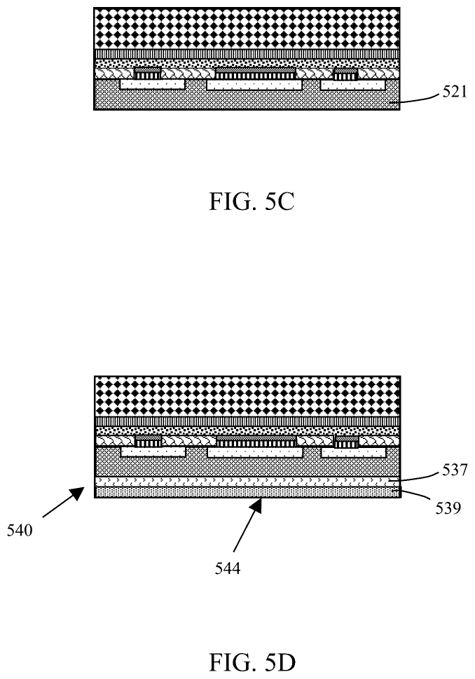

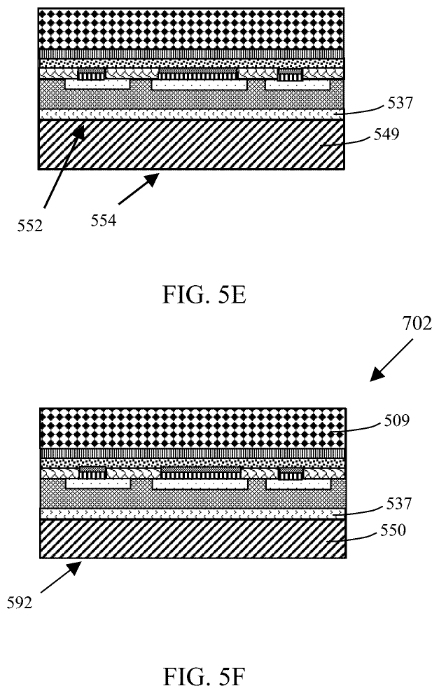

In block 202, referring now to FIG. 5F, an upper device portion 702 is provided. The upper device portion 702 may be fabricated by the sub-steps of FIG. 3 to include a first carrier 509 attached to a front surface of device wafer 502 through a release layer 510 and an adhesive layer 543, and a first copper layer 550 attached to a back surface of device wafer 502 through a titanium layer 537. The first carrier 509 helps to provide the mechanical strength to prevent the thinned semiconductor substrate 521 and the first copper layer 550 from warpage in which the back surface 592 of the first copper layer 550 would curve inward without the support of the first carrier 509 due to increased stress built up in the process of plating the first copper layer. Block 202 may be followed by block 204.

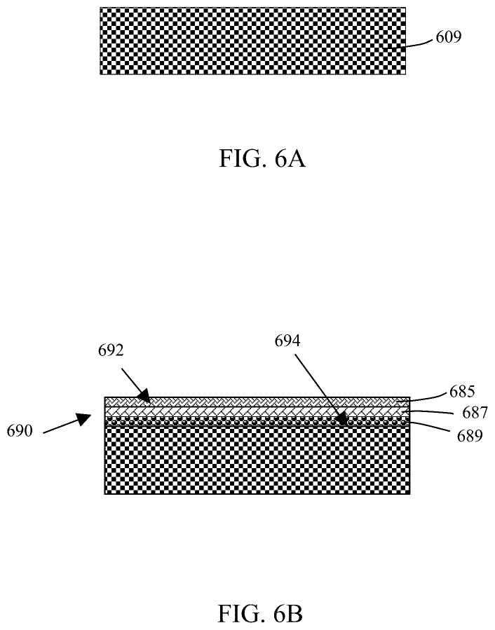

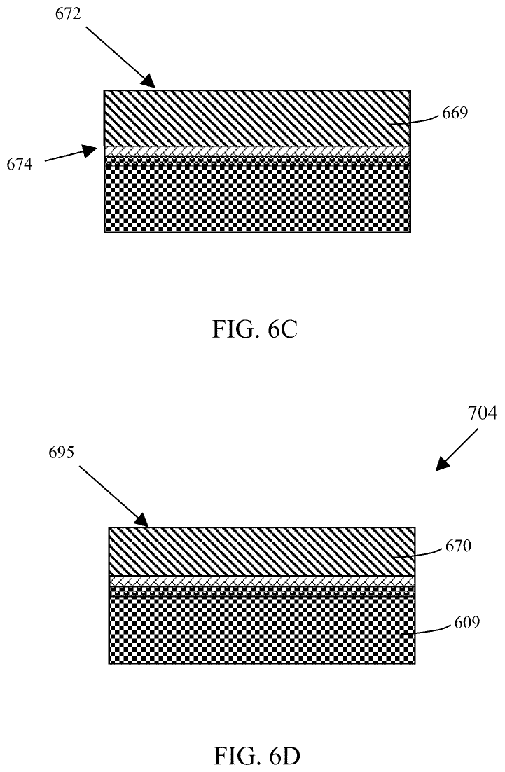

In block 204, referring now to FIG. 6D, a lower carrier portion 704 is provided. The lower carrier portion 704 may be fabricated by the sub-steps of FIG. 4 to include a second copper layer 670 attached to a second carrier 809 through a release layer 689 and a coating metal layer 687. The second carrier 809 helps to provide the mechanical strength to prevent the second copper layer 670 from warpage in which the front surface 695 of the second copper layer 670 would curve inward without the support of the second carrier 809 due to increased stress built up in the process of plating the second copper layer. Block 204 may be followed by block 206.

In block 206, referring now to FIG. 7A, a Cu—Cu bonding process is applied so that the polished back surface 592 of the first copper layer 550 of the upper device portion 702 is bonded to the polished front surface 695 of the second copper layer 670 of the lower carrier portion 704. Thermo-compression bonding (TCB) may be used. However high pressure and high temperature condition involved in TCB process may cause undesirable effect on the semiconductor device. A Surface Activated Bonding (SAB) process that provide strong bonding result at room temperature and low mechanical pressure is preferred.

Standard SAB method is based on surface bombardment by Ar beam in ultra-high vacuum to clean the surfaces so that they can be bonded very strongly at room temperature without heat treatment. Detail description of the method can be found in “Surface Activated Bonding Method for Low Temperature Bonding”, 2018 7th Electronic System-Integration Technology Conference (ESTC). In block 206, bonded copper atoms are formed between the first copper layer 550 and the second copper layer 670. When the two inward curving surfaces are forced to bond together, opposite stresses balance out each other. Block 206 may be followed by block 208.

In block 208, referring now to FIG. 7B, a de-bonding process is applied so that the first carrier 509 of FIG. 5F and a second carrier 809 of FIG. 6D (including the release layer 510 and the adhesive layer 543 of FIG. 5B and the release layer 689 of FIG. 6B) are removed. The gold layer 529 is exposed at the front and the coating metal layer 687 is exposed at the back. The coating metal layer 687 may be retained such that the final CSP packaged device (semiconductor package 100) includes the coating metal layer 190. Alternatively, the coating metal layer 687 may be removed by metal etching process so that the back surface 174 of the second thick metal layer 170 would exposed in the finished CSP device. Because the first and second copper layers have opposite directions of warpage without the supporting carriers, stress can be balanced out by bonding the second copper layer to the first copper layer with a selected thickness of the second copper layer matching stress of the first copper layer and the semiconductor substrate layer. The wafer can maintain substantially warpage free after the de-bonding process even under temperature stress. In examples of the present disclosure, the thickness of the second copper layer is larger than the thickness of the first copper layer. Block 208 may be followed by block 210.

In block 210, referring now to FIG. 7C, a tape 791 is applied. Block 210 may be followed by block 212. Alternatively, the tape 791 may be applied to back surface 794 of the coating metal layer 687 right after the second carrier 809 is de-bonded in block 208.

In block 212, referring now to FIG. 7D, a singulation process, along the scribe lines 798, is provided so that a plurality of semiconductor packages 799 are formed. In examples of the present disclosure, each of the plurality of semiconductor packages 799 is a common-drain metal-oxide-semiconductor field-effect transistor (MOSFET) chip scale package (CSP) for battery protection application. Two gates and a plurality of sources are on a front surface of the common-drain MOSFET CSP. A common-drain is on a back surface of the common-drain MOSFET CSP. In one example, a horizontal dimension of each of the plurality of semiconductor packages 799 is 3.4 mm by 2.0 mm.

In examples of the present disclosure, each of the plurality of semiconductor packages 799 excludes a compound layer (for example, a compound layer 180of FIG. 3 and paragraph [0021] of US Patent Application Publication No. 2023/0307325 to Lv et al.). Each of the plurality of semiconductor packages 799 excludes a molding encapsulation (for example, a molding encapsulation 198 of FIG. 1 and paragraph [0013] of 2023/0420340). Each of the plurality of semiconductor packages 799 excludes an adhesive layer between a first thick metal layer 150 (a first copper layer) and a second thick metal layer 170 (a second copper layer). The plurality of semiconductor packages 799 maintain substantially warpage free even under temperature stress. In examples of the present disclosure, a total thickness variation (TTV) of each of the plurality of semiconductor packages 799 is less than 3 microns.

FIG. 3 is a flowchart of a process 202P, representing sub-steps of block 202, to prepare an upper device portion 702 in examples of the present disclosure. FIGS. 5A, 5B, 5C, 5D, 5E, and 5F show the cross sections of the corresponding sub-steps of the process of FIG. 3 in examples of the present disclosure. For simplicity, the process to make a single semiconductor package is shown in FIGS. 5A, 5B, 5C, 5D, 5E, and 5F. The number of semiconductor packages fabricated by a single wafer may vary. The process 202P may start from block 302.

In block 302, referring now to FIG. 5A, a device wafer 502 is provided. The device wafer 502 comprises a semiconductor substrate 520 and a plurality of contact pads 530. The semiconductor substrate 520 has a front surface 522 and a back surface 524 opposite the front surface 522 of the semiconductor substrate 520. The plurality of contact pads 530 are attached to the front surface 522 of the semiconductor substrate 520. In examples of the present disclosure, a thickness of the semiconductor substrate 520 is more than 50 microns.

In examples of the present disclosure, each of the plurality of contact pads 530 contains nickel layer 527 and gold layer 529. The plurality of contact pads 530 comprise a plurality of aluminum sections 532. The plurality of aluminum sections 532 are disposed at the front surface 522 of the semiconductor substrate 520. The plurality of passivation sections 534 extend above edges of the plurality of aluminum sections 532. Block 302 may be followed by block 304.

In block 304, referring now to FIG. 5B, a first carrier 509 is attached to the front of the device wafer 502 by a release layer 510 and an adhesive layer 543. In examples of the present disclosure, the release layer 510 is coated on a back surface of the first carrier 509 and the adhesive layer 543 is coated onto the front surface of the device wafer 502. The adhesive layer 543 surrounds and protects the plurality of contact pads 530. In one example, the first carrier 509 is composed of a metal material. In another example, the first carrier 509 is composed of a glass material. The bonding of the first carrier 509 will increase the strength of the device wafer 502 so as to reduce warpage during subsequent processing steps. In examples of the present disclosure, block 304 is a bonding process including a heat cured process or an ultra-violet (UV) cured process in a bonding machine.

The release layer 510 has a front surface 512 and a back surface 514 opposite the front surface 512 of the release layer 510. The front surface 512 of the release layer 510 is directly attached to a back surface of the first carrier 509. Block 304 may be followed by block 306.

In block 306, referring now to FIG. 5C, a thinning process is applied over the back surface 524 of the semiconductor substrate 520 so as to formed a thinned semiconductor substrate 521. In examples of the present disclosure, a thickness of the thinned semiconductor substrate 521 is in a range from 15 microns to 35 microns. The thinning process may include back side grinding and back side etching. Block 306 may be followed by block 308.

In block 308, referring now to FIG. 5D, a seed layer 540 is deposited over a back surface of the thinned semiconductor substrate 521 by PVD or evaporation. The seed layer 540 is directly attached to the back surface of the thinned semiconductor substrate 521. In examples of the present disclosure, the seed layer 540 comprises a thin titanium layer 537 and a thin seed copper layer 539. In one example, a thickness of the titanium layer 537 is 0.1 micron. A thickness of the thin seed copper layer 539 is 0.2 micron. Block 308 may be followed by block 310.

In block 310, referring now to FIG. 5E, a copper layer 549 is formed by electroplating a thick copper layer over the thin seed copper layer 539. The copper layer 549 has a front surface 552 and a back surface 554 opposite the front surface 552 of the copper layer 549. The front surface 552 of the copper layer 549 is attached to the back surface of the thinned semiconductor substrate 521 through titanium layer 537. The increase of copper layer thickness in the electroplating process builds up stress. The first carrier 509 helps to provide the mechanical strength to prevent the thinned semiconductor substrate 521 and the copper layer 549 from warpage in which the back surface 554 of copper layer 549 would curve inward without the support of the first carrier 509 due to increased stress built up in the process of plating the copper layer. Block 310 may be followed by block 312.

In block 312, referring now to FIG. 5F, a polishing process is applied over a back surface 544 of the copper layer 549 so as to form a first copper layer 550 with a polished back surface 592. More specifically, Cu chemical-mechanical-polishing (CMP) is applied to facilitate a smooth surface with surface roughness Ra≤0.6 nm to ensure strong bonding strength in SAB process. The first carrier 509 helps to provide the mechanical strength to prevent the thinned semiconductor substrate 521 and the first copper layer 550 from warpage in which the back surface 592 of the first copper layer 550 would curve inward without the support of the first carrier 509 due to increased stress built up in the process of plating the copper layer. In one example, a thickness of the first copper layer 550 is in a range from 10 to 40 microns. A sum of a thickness of the first copper layer 550 and a thickness of the second copper layer 670 of FIG. 6D is in a range from 25 microns to 80 microns. The lower limit 25 microns is to maintain the conductivity of the first copper layer 550 and the second copper layer 670 above a pre-determined conductivity value. The upper limit 80 microns is to maintain total thickness of each of the plurality of semiconductor packages 799 below a pre-determined thickness value. Therefore, the upper device portion 702 is formed.

FIG. 4 is a flowchart of a process 204P, representing sub-steps of block 204, to prepare a lower carrier portion 704 in examples of the present disclosure. FIGS. 6A, 6B, 6C, and 6D show the cross sections of the corresponding sub-steps of the process of FIG. 4 in examples of the present disclosure. For simplicity, the process to make a single semiconductor package is shown in FIGS. 6A, 6B, 6C, and 6D. The number of semiconductor packages fabricated by a single wafer may vary. The process 204P may start from block 602.

In block 602, referring now to FIG. 6A, a second carrier 609 is provided. In one example, the second carrier 609 is composed of a metal material. In another example, the second carrier 609 is composed of a glass material. Block 602 may be followed by block 604.

In block 604, referring now to FIG. 6B, a coating layer 690 is formed. The coating layer 690 has a front surface 692 and a back surface 694 opposite the front surface 692 of the coating layer 690. The back surface 694 of the coating layer is attached to the second carrier. In examples of the present disclosure, the coating layer 690 comprises a coating metal layer 687 deposited on top of a release layer 689. A thin seed copper layer 685 is then deposited on top of the coating metal layer 687. In one example, a thickness of the thin seed copper layer 685 is 0.2 micron. A thickness of the coating metal layer 687 is 0.1 micron. In one example, the coating metal layer 687 comprises titanium. In another example, the coating metal layer 687 comprises nickel. The release layer 689 is first coated on top surface of second carrier 609 then baked at 180 degree C. for 30 minutes to facilitate good adhesion. After that Titanium or Nickel is deposited onto the release layer 689 followed by Copper deposition by sputtering. In one example, the second carrier 609 is a glass substrate and the release layer 689 is a laser release layer. Upon laser irradiation, the laser release layer 689 becomes powder, thereby losing adhesion, during the de-bonding process of block 208 of FIG. 2. Block 604 may be followed by block 606.

In block 606, referring now to FIG. 6C, a copper layer 669 is formed by electroplating a thick copper over the back surface of the thin seed copper layer 685. The copper layer 669 has a front surface 672 and a back surface 674 opposite the front surface 672 of the copper layer 669. The back surface 674 is attached to the coating metal layer 687. The increase of copper layer thickness in the electroplating process builds up stress. The second carrier 609 helps to provide the mechanical strength to prevent the copper layer 669 from warpage in which the front surface 672 of the copper layer 669 would curve inward without the support of the second carrier 609 due to increased stress built up in the process of plating the copper layer. In examples of the present disclosure, the parameters for electroplating the copper layer 669 are substantially identical to those parameters in electroplating the copper layer 549 such that the mechanical and thermal properties of the copper layer 669 would be substantially identical to the copper layer 549. In examples of the present disclosure, the thickness of the copper layer 669 is less than the thickness of the copper layer 549. Block 606 may be followed by block 608.

In block 608, referring now to FIG. 6D, a polishing process is applied over a front surface 672 of the copper layer 669 so as to form a second copper layer 670 with a polished front surface 695. More specifically, Cu chemical-mechanical-polishing (CMP) is applied to facilitate a smooth surface with surface roughness Ra≤0.6 nm to ensure strong bonding strength in SAB process. The second carrier 609 helps to provide the mechanical strength to prevent the second copper layer 670 from warpage in which the front surface 695 of the second copper layer 670 would curve inward without the support of the second carrier 609 due to increased stress built up in the process of plating the copper layer. In examples of the present disclosure, the parameters for CMP the copper layer 669 are substantially identical to those parameters in CMP the copper layer 549 such that the mechanical and thermal properties of the second copper layer 670 would be substantially identical to the first copper layer 550. In examples of the present disclosure, a thickness of the second copper layer 670 is in a range from 10 microns to 45 microns. In examples of the present disclosure, a sum of a thickness of the first copper layer 550 and a thickness of the second copper layer 670 is in a range from 25 microns to 80 microns and the thickness of the second copper layer 670 is larger than the thickness of the first copper layer 550. Therefore, the lower carrier portion 704 is formed.

Those of ordinary skill in the art may recognize that modifications of the embodiments disclosed herein are possible. For example, a total number of the plurality of contact pads 130 may vary. Other modifications may occur to those of ordinary skill in this art, and all such modifications are deemed to fall within the purview of the present invention, as defined by the claims.

1. A semiconductor package comprising:
a semiconductor substrate having a front surface and a back surface opposite the front surface of the semiconductor substrate;
a plurality of contact pads attached to the front surface of the semiconductor substrate;
a seed layer;
a first thick metal layer having a front surface and a back surface opposite the front surface of the first thick metal layer, the first thick metal layer attached to the back surface of the semiconductor substrate through the seed layer; and
a second thick metal layer having a front surface and a back surface opposite the front surface of the second thick metal layer, the front surface of the second thick metal layer being directly attached to the back surface of the first thick metal layer.

2. The semiconductor package of claim 1, wherein the first thick metal layer and the second thick metal layer are configured as two layers with opposite stress states.

3. The semiconductor package of claim 1, wherein the first thick metal layer and the second thick metal layer comprise copper.

4. The semiconductor package of claim 3, wherein the semiconductor package excludes a compound layer; wherein the semiconductor package excludes a molding encapsulation; and
wherein the direct attachment of the first thick metal layer and the second thick metal layer excludes an adhesive layer between the first thick metal layer and the second thick metal layer.

5. The semiconductor package of claim 3, wherein a thickness of the first thick metal layer is in a range from 10 microns to 40 microns.

6. The semiconductor package of claim 3, further comprising a coating metal layer comprising titanium (Ti) or nickel (Ni) attached to the back surface of the second thick metal layer.

7. The semiconductor package of claim 3, wherein the seed layer comprises titanium.

8. The semiconductor package of claim 3, wherein a thickness of the semiconductor substrate is in a range from 15 microns to 35 microns; and wherein a sum of a thickness of the first thick metal layer and a thickness of the second thick metal layer is in a range from 25 microns to 80 microns.

9. The semiconductor package of claim 1, wherein the semiconductor package is a common-drain metal-oxide-semiconductor field-effect transistor (MOSFET) chip scale package (CSP) for battery protection application.

10. A method for fabricating a plurality of semiconductor packages, the method comprising the steps of:
providing an upper device portion comprising the sub-steps of:
providing a device wafer comprising
a semiconductor substrate having a front surface and a back surface opposite the front surface of the semiconductor substrate; and
a plurality of contact pads formed on the front surface of the semiconductor substrate;
bonding a first carrier to the front surface of the device wafer;
applying a thinning process over the back surface of the semiconductor substrate so as to formed a thinned semiconductor substrate; and
forming a first copper layer on a back surface of the thinned semiconductor substrate, the first copper layer having a back surface away from the thinned semiconductor substrate;
providing a lower carrier portion comprising the sub-steps of:
providing a second carrier having a front surface and a back surface opposite the front surface of the second carrier; and
forming a second copper layer on the front surface of the second carrier, the second copper layer having a front surface away from the second carrier;
bonding the back surface of the first copper layer of the upper device portion to the front surface of the second copper layer of the lower carrier portion;
applying a de-bonding process removing the first carrier and the second carrier; and
applying a singulation process to form the plurality of semiconductor packages.

11. The method of claim 10, wherein each of the plurality of semiconductor packages excludes an adhesive layer between the first copper layer and the second copper layer.

12. The method of claim 11, wherein the step of bonding the back surface of the first copper layer of the upper device portion to the front surface of the second copper layer of the lower carrier portion applies a surface activation bonding (SAB) process.

13. The method of claim 12, before the step of bonding the back surface of the first copper layer of the upper device portion to the front surface of the second copper layer of the lower carrier portion, further comprising the sub-steps of chemical-mechanical polishing (CMP) the back surface of the first copper layer and the front surface of the second copper layer to facilitate Ra less than or equal to 0.6 nm surface smoothness.

14. The method of claim 13, wherein a thickness of the first copper layer is in a range from 10 microns to 40 microns.

15. The method of claim 10, wherein the sub-step of forming the second copper layer comprises depositing a titanium or nickel layer and a copper seed layer followed by electroplating a thick copper layer.

16. The method of claim 15, further comprising coating a release layer on the front surface of the second carrier before depositing the titanium or nickel layer.

17. The method of claim 10, wherein the sub-step of forming the first copper layer comprises depositing a titanium layer and a copper seed layer followed by electroplating a thick copper layer.

18. The method of claim 10, wherein a thickness of the semiconductor substrate is in a range from 15 microns to 35 microns; and wherein a sum of a thickness of the first copper layer and a thickness of the second copper layer is in a range from 25 microns to 80 microns.

19. The method of claim 10, wherein the sub-step of bonding the first carrier to the front surface of the device wafer comprises coating a release layer and coating an adhesive layer on the front surface of the device wafer.

20. The method of claim 10, wherein each of the plurality of semiconductor packages is a common-drain metal-oxide-semiconductor field-effect transistor (MOSFET) chip scale package (CSP) for battery protection application.
